(19) United States
(12) Patent Application Publication
(10) Pub. No.: US 2008/0163012 A1
(43) Pub. Date: Jul. 3, 2008

(54) Apparatus for Configuring a USB PHY to Loopback Mode

(76) Inventor: Radhakrishnan Nair, Fremont, CA (US)

Correspondence Address: BRINKS HOFER GILSON & LIONE/SanDisk, P.O. BOX 10395, CHICAGO, IL, 60610, US

(21) Appl. No.: 11/618,852

(22) Filed: Dec. 31, 2006

(51) Int. Cl. G01R 31/28

(52) U.S. Cl. 714/716

(57) ABSTRACT

A circuit includes a universal serial bus physical layer interface (USB PHY), programmable storage elements in communication with control inputs of the USB PHY, and a processor to set the programmable storage elements. The processor initiates the loopback mode of the USB PHY by sending the appropriate control signal sequence to the programmable storage elements. The processor may also enable the generation of hardware generated or programmed test data.

### FIELD OF THE DISCLOSURE

The present disclosure is related to the field of serial interfaces. In particular, an application specific integrated circuit having a processor and a universal serial bus physical layer interface configurable to loopback mode by the processor through programmable storage elements is disclosed.

### BACKGROUND

Memory devices such as thumb drives process data in parallel for storage and in series for input and/or output to a host or other external device. The memory devices typically have an application specific integrated circuit (ASIC) having a universal serial bus physical layer interface (USB PHY) to convert the data between serial and parallel formats and to extract and interpret high speed signals.

An ASIC tester is typically used to test the ASIC, including the USB PHY, when it is produced. The ASIC tester has a number of features, including the capability to configure the control inputs of the USB PHY to a loopback mode, so that parallel data is serialized and then converted back to parallel by the USB PHY. The input parallel data is then compared to the output parallel data and test results are generated.

In reliability testing, the USB PHY is tested for extended periods of time (up to 1000 hours) while environmental parameters are changed and the operation of the USB PHY is observed. For performing reliability tests, a low cost test is preferred over a full ASIC test. A low cost test can be realized by having fewer required external test functions.

### SUMMARY

There is a presently recognized need to initiate loopback mode in a USB PHY without the need for an external tester.

The present invention is defined by the claims and nothing in this section should be taken as a limitation on those claims.

According to first aspect of the disclosure, an ASIC has a USB PHY, a loopback control engine in communication with control inputs of the USB PHY, and a processor to set the status of programmable storage elements in the loopback control engine. The processor initiates the loopback mode of the USB PHY by sending the appropriate control signal sequence to the loopback control engine. The loopback control engine preferably has a programmable register having storage elements for receiving the control signal sequence.

Preferably, the processor is configured to enable the generation of hardware generated or programmable test data, and the ASIC has a multiplexer configured to communicate the test data to the USB PHY. A first memory may be integrated in the ASIC to receive test data that is also communicated to the USB PHY. A second memory may be integrated in the ASIC to receive serialized-de-serialized test data returned by the USB PHY. The ASIC may include a first counter to tally a number of loopback operations executed by the USB PHY. A second counter may tally a number of matches between the data in the first memory and the data in the second memory at the completion of each loopback operation.

The preferred embodiments will now be described with reference to the attached drawings.

### BRIEF DESCRIPTION OF THE DRAWINGS

FIG. 1 is a block diagram of an ASIC having a processor and a USB PHY that can be configured to loopback mode by the processor.

FIG. 2 is a block diagram of an ASIC having the components of FIG. 1 and additional components for use in testing the USB PHY and for supporting data flow between a memory storage element and a USB PHY.

FIG. 3 shows an engine auxiliary block having a preferred set of storage locations in programmable registers in communication with the USB PHY and processor of FIG. 2.

FIG. 4 is a diagram showing preferred components in the ASIC of FIG. 2 for use to test the USB PHY.

FIG. 5 shows a version of acts to configure a USB PHY to loopback mode.

### DETAILED DESCRIPTION OF THE PRESENTLY PREFERRED EMBODIMENTS

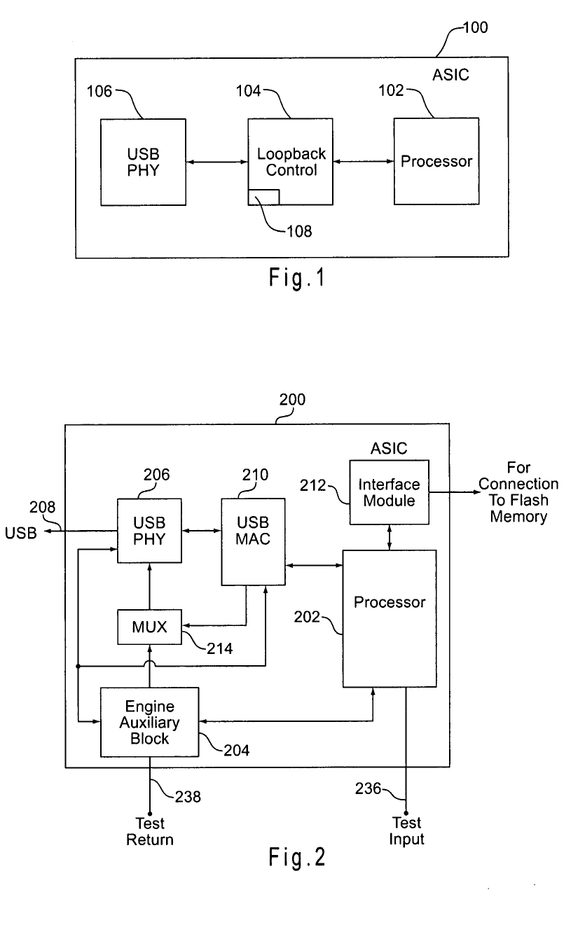

FIG. 1 shows an ASIC 100 having a processor 102, a loopback control engine 104, and a USB PHY 106. The loopback control engine 104 has storage elements, for example 108, in communication with control inputs (not shown) of the USB PHY 106. The state (or sequence) of the control inputs (not shown) determines whether the USB PHY 106 is configured to operate in loopback mode. The loopback control engine 104 allows the processor 102 to configure the USB PHY 106 to operate in loopback mode. In one version, the loopback control engine 104 has a set of registers that are programmable by the processor 102. A USB PHY from Chipidea (Portugal) or other PHY IP supplier may be implemented in the ASIC.

The processor 102 may download and execute a set of instructions for configuring the USB PHY 106 to operate in loopback mode. The instructions may include a write sequence, for example, to the loopback control engine 104 to provide the control signal sequence required by the USB PHY 106 for loopback mode operation. The processor 102 may also download instructions for executing a reliability (or other) test, and may erase the instructions upon completion of the test.

FIG. 2 is a block diagram of an ASIC 200 that implements the components of FIG. 1 and that may comprise a part of a USB peripheral device such as a Flash memory thumb drive. The USB peripheral device may be configured to connect with a host (not shown) via a USB communication line 208. The host device may be the USB port of any device having USB capability, such as a personal computer or other microprocessor-based device such as a cell phone or MP3 player. The USB communication line 208 may be a direct USB connection of the USB peripheral device to the host device via a standard USB connector or may include intervening USB functions. The ASIC 200 preferably includes an interface module 212 for connecting to non-volatile memory, such as a Flash memory.

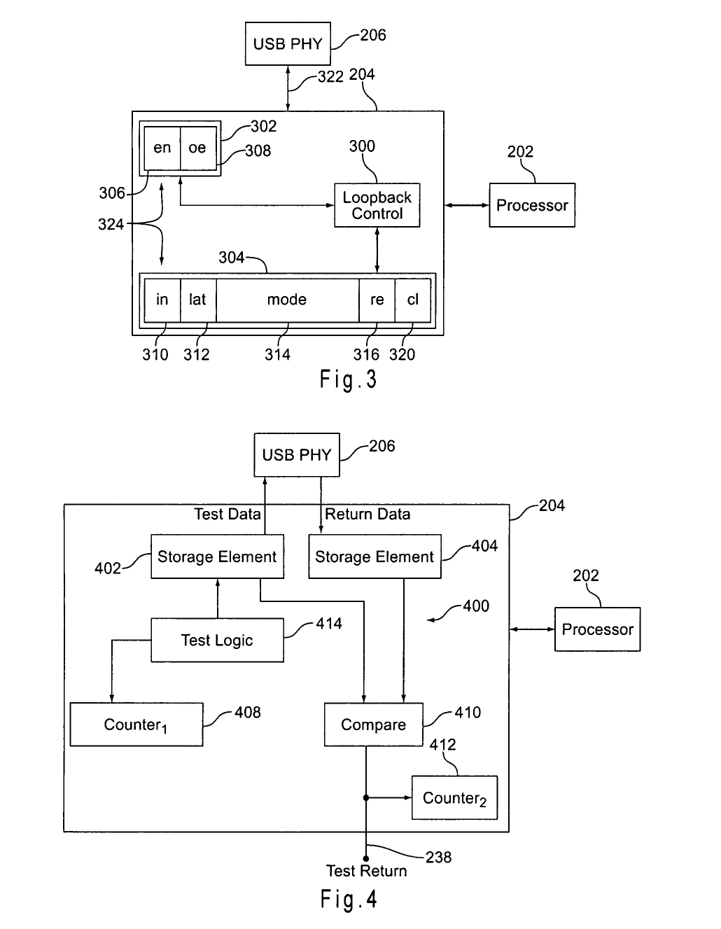

The ASIC 200 includes an engine auxiliary block 204 having a loopback control engine 300, shown in FIG. 3. The loopback control engine 300 controls programmable registers 324 that have storage locations that are connected to control inputs of the USB PHY 206 through connectors 322. In a preferred version, the programmable registers 324 are a firmware USB PHY loopback enable register 302 and a firmware USB PHY loopback control register 304.

The firmware USB PHY loopback enable register 302 has an enable (en) storage location 306 to hold the setting that determines whether the control inputs of the USB PHY 206 may be controlled by the firmware USB PHY loopback control register 304 storage locations. The enable (en) storage location 306 setting either enables or disables firmware control of the USB PHY loopback mode.

The firmware USB PHY loopback enable register 302 has an output enable (oe) storage location 308 to hold the setting that controls whether the USB PHY 206 outputs loopback test return data to an ASIC 200 output pin.

The firmware USB PHY loopback control register 304 has an initiate (in) storage location 310 to hold the setting that initiates loopback mode. In a preferred version, the initiate (in) storage location 310 is a bit that is set only after the other USB PHY loopback control register 304 storage locations have been set for the desired operational mode, such as loopback mode.

An operational mode (mode) storage location 314 holds the code that sets the operational mode, such as loopback mode, of the USB PHY 206. A latch (lat) storage location 312 is set to latch the test mode value in the operational mode (mode) storage location 314. A reset (re) storage location 316 is set to immediately take the USB PHY 206 out of loopback mode. A clock control (cl) storage location 320 controls the clock produced by the USB PHY 206.

Referring to FIG. 4, the engine auxiliary block 204 may also include test components 400 for use in testing the USB PHY 206 in loopback mode. The test components 400 may include a test logic circuit 414 in communication with the processor 202. In one version, the test logic circuit 414 outputs test data upon receipt of an enable signal from the processor 202. The test data may be obtained from a hardware data circuit (hardware test data) or, alternatively, from test data registers that are programmable by the processor 202 (programmed test data). The test logic circuit 414 may include the hardware data circuit (not shown) and the test data registers (not shown).

The test data used for each loopback test may be received by the USB PHY 206 by way of a multiplexer 214 (FIG. 2) in communication with the test data registers. The multiplexer 214 is controlled by the engine auxiliary block 204 that selects between the normal function data from the USB media access control circuit (USB MAC) 210 and the test data so as to provide test data in a sequence to the USB PHY 206 when loopback testing is enabled. The test data sequence may be programmable by the processor 202 or may be hardware controlled. The engine auxiliary block 204 monitors and controls the test sequence.

The test data that is communicated to the USB PHY 206 by the test logic circuit 414 is also held in a test data storage element 402 in the engine auxiliary block 204. In loopback mode, the USB PHY 206 serializes and de-serializes the test data and outputs return data to a return data storage element 404 in the engine auxiliary block 204. A compare circuit 410 compares the test data in the test data storage element 402 to the return data in the return data storage element 404 and provides an output signal to a test return pin 238. The compare circuit 410 may output a “high” signal each time the data in the test data storage element 402 matches the data in the return data storage element 404 at the completion of a loopback operation.

The auxiliary block 204 may also have two counters to tally the number of times loopback has been initiated (counter₁ 408) and the number of matches between the test data and return data (counter₂ 412). The processor 202 may receive the data from counter₁ 408 and counter₂ 412 and generate test results for use in evaluating the USB PHY 206.

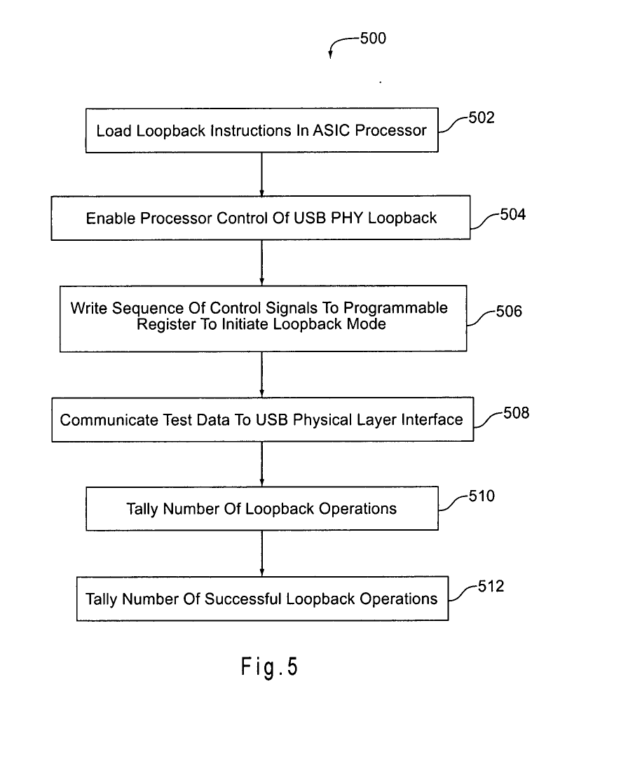

FIG. 5 shows acts 500 for configuring a USB PHY to loopback mode and for performing a test. At Act 502, processor executable instructions for enabling and initiating loopback operation are loaded in the processor in the ASIC. The instructions preferably include write commands for writing data to a programmable register, or other storage element(s), in communication with the USB PHY. The instructions may be loaded by way of a test or debug input 236, for example, or may have been previously loaded and stored in the processor's memory. The instructions may include instructions for testing the USB PHY in loopback mode.

At Act 504, a control bit of the USB PHY is set to enable the processor to control the operation mode of the USB PHY. At Act 506, the processor outputs a sequence of control signals to the programmable register in communication with the operational mode control inputs of the USB PHY. At Act 508, test data is communicated to the USB PHY. The test data may be communicated from the processor, a register, a memory, or other source.

In a preferred version, the number of loopback operations completed by the USB PHY are tallied (Act 510), and the number of successful loopback operations are tallied (Act 512). A successful loopback operation corresponds to having test data match return test data. The test data may be output to the processor or other device.

The following concurrently filed (Dec. 31, 2006), commonly owned applications are incorporated by reference herein: “Method for Configuring a USB PHY to Loopback Mode” (having attorney reference number SDA-1095x (10519/203)); “Method for Performing Full Transfer Automation in a USB Controller” (having attorney reference number SDA-1094x (10519/201)); “USB Controller with Full Transfer Automation” (having attorney reference number SDA-1094y (10519/202)); “Selectively Powering Data Interfaces” (having attorney reference number SDA-1076x); “Selectively Powered Data Interfaces” (having attorney reference number SDA-1076y); “Testing Quiescent Current of Power Islands Using Respective Scan Chains” (having attorney reference number SDA-1088x); “Power Islands with Respective Scan Chains for Testing Quiescent Current” (having attorney reference number SDA-1088y); “Chip with Two Types of Decoupling Capacitors” (having attorney reference number SDA-1089y); “Decoupling with Two Types of Capacitors” (having attorney reference number SDA-1089x); “Integrated Circuit with Protected Internal Isolation” (having attorney reference number SDA-1090y); “Internally Protecting Lines at Power Island Boundaries” (having attorney reference number SDA-1090x); “Module with Delay Trim Value Updates on Power-Up” (having attorney reference number SDA-1091y); “Updating Delay Trim Values” (having attorney reference number SDA-1091x); “Systems and Integrated Circuits with Inrush-Limited Power Islands” (having attorney reference number SDA-1092y); “Limiting Power Island Inrush Current” (having attorney reference number SDA-1092x); “Systems and Circuits with Programmable and Localized Power-Valid Detection” (having attorney reference number SDA-1093y); “Programmably and Locally Detecting Power Valid” (having attorney reference number SDA-1093x); “De-Glitching Method” (having attorney reference number SDA-1096x); and “De-Glitching Circuit” (having attorney reference number SDA-1096y).

All of the discussion above, regardless of the particular implementation being described, is exemplary in nature, rather than limiting. For example, although specific components of the ASIC are described, methods, systems, and articles of manufacture consistent with the ASIC may include additional or different components. For example, the processor may be implemented by one or more of: control logic, hardware, a microprocessor, microcontroller, application specific integrated circuit (ASIC), discrete logic, or a combination of circuits and/or logic. Any act or combination of acts may be stored as instructions in computer readable storage medium. Memories may be DRAM, SRAM, Flash or any other type of memory. Programs may be parts of a single program, separate programs, or distributed across several memories and processors.

While various embodiments of the invention have been described, it will be apparent to those of ordinary skill in the art that many more embodiments and implementations are possible within the scope of the invention. Accordingly, the invention is not to be restricted except in light of the attached claims and their equivalents.

What is claimed is:

1. An apparatus comprising:
a universal serial bus physical layer interface (USB PHY) integrated in an application specific integrated circuit (ASIC); and
a processor integrated in the ASIC and having executable instructions to configure the USB PHY to function in a loopback mode.

2. The apparatus of claim 1 comprising a storage element in communication with the processor and the USB PHY to enable processor control of the loopback mode.

3. The apparatus of claim 2 wherein the storage element is included in a loopback control engine.

4. The apparatus of claim 1 comprising a storage element in communication with the USB PHY to enable the processor to initiate the loopback mode.

5. The apparatus of claim 1 comprising a multiplexer integrated in the ASIC to communicate selectable test data to the USB PHY.

6. The apparatus of claim 5 comprising a test logic circuit to provide the selectable test data to a test data storage element integrated in the ASIC.

7. The apparatus of claim 1 comprising programmable test data registers in communication with the processor to communicate test data to the USB PHY.

8. The apparatus of claim 1 comprising a first memory integrated in the ASIC to receive test data to communicate to the USB PHY and a second memory to receive return data from the USB PHY.

9. The apparatus of claim 8 comprising a counter integrated in the ASIC to tally a number of matches between the data in the first memory and the data in the second memory at the completion of each of a plurality of loopback operations.

10. The apparatus of clam 1 comprising a counter integrated in the ASIC to tally a number of loopback operations executed by the USB PHY.

11. An apparatus comprising:
a storage element in an application specific integrated circuit (ASIC) to receive control signals to initiate loopback mode in a universal serial bus physical layer interface (USB PHY); and
a processor integrated in the ASIC and having executable instructions to communicate the control signals to the storage element.

12. The apparatus of claim 11 comprising a loopback control engine having the storage element.

13. The apparatus of claim 11 comprising a multiplexer integrated in the ASIC to communicate selectable test data to the USB PHY.

14. The apparatus of claim 13 comprising a test logic circuit to provide the selectable test data to a test data storage element integrated in the ASIC.

15. The apparatus of claim 11 comprising programmable test data registers in communication with the processor to communicate programmable test data to the USB PHY.

16. The apparatus of claim 11 comprising a first memory integrated in the ASIC to receive test data to communicate to the USB PHY and a second memory to receive return data from the USB PHY.

17. The apparatus of claim 16 comprising a counter integrated in the ASIC to tally a number of matches between the data in the first memory and the data in the second memory at the completion of each of a plurality of loopback operations.

18. The apparatus of clam 11 comprising a counter integrated in the ASIC to tally a number of a number of loopback operations executed by the USB PHY.

19. An apparatus comprising:
a universal serial bus physical layer interface (USB PHY) in an application specific integrated circuit (ASIC); and
means for configuring the USB PHY into loopback mode without receiving signals from outside the ASIC.
